(19) United States
(12) Patent Application Publication
(10) Pub. No.: US 2013/0320987 A1
(43) Pub. Date: Dec. 5, 2013

(54) Method for measuring the reproducibility of N unitary ion exchange membrane/electrode assemblies using polluting agent delivery

(71) Applicant: COMMISSARIAT A L'ENERGIE ATOMIQUE ET AUX ENERGIES ALTERNATIVES, Paris (FR)

(72) Inventors: Sylvain PASSOT, Tullins (FR); Olivier LEMAIRE, Les Abrets (FR); Christel FAURE, Tullins (FR); Alejandro FRANCO, Eybens (FR)

(73) Assignee: COMMISSARIAT A L'ENERGIE ATOMIQUE ET AUX ENERGIES ALTERNATIVES, Paris (FR)

(21) Appl. No.: 13/900,301

(22) Filed: May 22, 2013

(30) Foreign Application Priority Data
May 29, 2012 (FR) 12 54917

(51) Int. Cl. G01R 31/36

(52) U.S. Cl. CPC G01R 31/3648
USPC 324/425

(57) ABSTRACT

A method for measuring the reproducibility of N unitary ion exchange membrane/electrode assemblies, where N is an integer strictly greater than 1, each assembly containing an ion exchange membrane located between an anode fed with a first stream and a cathode fed with a second stream and possessing cell voltage characteristics, comprises the following steps: delivering to each unitary assembly a stream containing at least one polluting species for a given time; measuring at least one electrochemical parameter of each assembly; and comparing said measurements so as to evaluate the reproducibility of said assemblies.

### CROSS-REFERENCE TO RELATED APPLICATION

This application claims priority to foreign French patent application No. FR 1254917, filed on May 29, 2012, the disclosure of which is incorporated by reference in its entirety.

### FIELD OF THE INVENTION

The field of the invention is that of proton exchange membrane fuel cells (PEMFCs).

### BACKGROUND

PEMFCs are current generators the operating principle of which is based on the conversion of chemical energy into electrical power via a catalytic reaction of hydrogen and oxygen. Membrane electrode assemblies (MEAS) commonly called cell cores 1 are the basic elements of PEMFCs. They are composed of a polymer membrane 2 and catalytic layers 3 and 4 present on either side of the membrane. The membrane therefore separates the anode compartment 5 and the cathode compartment 6. The catalytic layers generally consist of platinum nanoparticles supported by carbon aggregates (generally carbon black). Gas diffusion layers 7 and 8 (carbon cloth, felt, etc.) are placed on either side of the MEA and serve as electrical conductors and ensure the uniform delivery of reactive gases and the removal of the water produced. At the anode, decomposition of the hydrogen adsorbed on the catalyst produces protons H⁺ and electrons e⁻. The protons then pass through the polymer membrane before reacting with oxygen at the cathode. Reaction of the protons with the oxygen at the cathode leads to the formation of water and to the production of heat, as shown in FIGS. 1a and 1b.

Depending on the method used to produce the hydrogen, the gas may contain impurities. It has been shown that carbon monoxide and sulfur-containing compounds have a particularly adverse effect on the operation of the cell. In this context, maximum concentration thresholds have been set in order to standardize the quality of the hydrogen used in fuel cells: 0.2 μmol/mol for CO and 0.004 μmol/mol for sulfur-containing compounds in the case of automotive applications, for example. These values, which were set by a technical standards committee, are subject to change.

With a view to mass producing electrodes and MEAs for PEM fuel cells, it is of paramount importance to have a reliable method for testing the reproducibility of the performance of MEAs, knowing that these components operate under a wide range of conditions.

The most commonly used conditions are the following:

a temperature between about 60° C. and 120° C.;

a pressure between atmospheric pressure and about 2 bars;

a relative humidity level between about 0% and 100%; and

a stoichiometry coefficient of between 1 and 2, or even more.

The anode is generally fed with a hydrogen-based fuel and the cathode with an oxygen-based oxidant.

Tests for validating fuel cell performance are generally carried out under the optimal operating conditions (temperature, pressure, humidity, flow rates, gas) of the PEM fuel cell, i.e. using pure hydrogen in order to ensure good operation of the anode and air or pure oxygen at the cathode. There are many electrochemical characterization methods. The catalyst powders and inks used may be studied ex situ, for example using the Koutecky-Levich rotating disk electrode (RDE) method.

The most common in situ characterization methods are the polarization curve method, cyclic voltammetry (CV)—as notably described in the patent application of O. Masaki, Electrode performance evaluation method and evaluation device of polymer electrolyte fuel cell, JP2004220786, 2004—and spectroscopy, because the electrode studied is fed with inert gas. Polarization curves and impedance spectra are obtained under operating conditions.

Optimum operating conditions may be defined or else suboptimal operating conditions may be employed.

The present invention relates to the latter category of conditions.

More precisely, prior art solutions possibly use one of the following techniques:

Measurement of the Capacitance of an MEA:

Nissan has proposed a simple and rapid solution for evaluating the performance of a PEMFC electrode (O. Masaki, Electrode performance evaluation method and evaluation device of polymer electrolyte fuel cell, JP2004220786, 2004). This solution is based on the measurement of the capacitance of an electrode exposed to an inert gas during a potential cycle. The capacitance of the double electrical layer increases with the area of the platinum-containing catalyst making contact with the electrolyte. However, this technical solution yields results that are not very representative of the performance of the electrode under the operating conditions of a PEM cell. It is rapid but imprecise.

Characterization of an MEA at Low Humidity Levels:

Toyota has proposed a test method using a low relative humidity level. Since the diffusion resistance of the gases used is higher at low humidity levels the performance attained is necessarily better under relatively high relative humidity conditions, as described in patent application: I. K. N. J. O. Shinobu, Method of testing membrane electrode assembly, JP2010251185, 2010. This solution mainly evaluates water management, the catalytic activity of the active layers having very little effect on the results.

Detection of a Defective MEA in a Stack:

One proposed solution for testing for defects in one MEA among an MEA stack consists in comparing the cell voltage measured for each MEA with the cell voltage averaged over the MEA stack, as described in Y. Sun, G. Xiao, Method for testing defects of single membrane electrode assembly in the fuel cell stack, CN101566594, 2009. The measurements are carried out under optimal conditions. The drawback is that this method does not allow slight differences in the performance of a number of MEAs to be detected.

Moreover, Samsung has protected a method and a testbed for testing an MEA stack, as described in patent C. G. Shin, Multi-MEA test station and multi-MEA method using the same, US 2008/0197857 A1, 2008. This testbed comprises the entire line for assembling MEAs, at constant temperature and humidity, into cells fed with fuel and oxidant, and the equipment for measuring the performance parameters of each MEA. The bed also enables activation of the MEAs and the purge process. This technical solution does not provide for injection of impurities such as carbon monoxide or hydrogen sulfide into the gas feed of the MEAs.

### SUMMARY OF THE INVENTION

In this context, the present invention proposes to characterize MEAs while employing a dose of a polluting entity, present in at least one of the feed streams, and advantageously amplifying the differences between various MEAs in a given series.

More precisely, the subject of the present invention is a method for measuring the reproducibility of the performance of N unitary ion exchange membrane/electrode assemblies, where N is an integer strictly greater than 1, each assembly containing an ion exchange membrane located between an anode fed with a first stream and a cathode fed with a second stream and possessing cell voltage characteristics, characterized in that it comprises the following steps:
delivering to each unitary assembly a stream containing at least one polluting species for a given time;
measuring at least one electrochemical parameter of each assembly; and
comparing said measurements so as to evaluate the reproducibility of said assemblies.

According to one variant of the invention, the electrochemical measurement is a measurement of the voltage between the anode and the cathode.

According to one variant of the invention, the electrochemical measurement is a measurement of the impedance of said cell.

According to one variant of the invention, the process comprises:
determining the standard deviation of all of said measurements; and
comparing said standard deviation with a predefined tolerance threshold value.

According to one variant of the invention, the measurement of the voltage of each assembly is carried out by applying a DC current.

According to one variant of the invention, the impedance measurement is carried out by applying current oscillations allowing the electrochemical impedance spectra of said assemblies to be defined.

According to one variant of the invention, the anode comprises a platinum-containing catalyst.

According to one variant of the invention, the anode comprises a catalyst containing platinum and ruthenium.

According to one variant of the invention, at least one polluting species is delivered to the anode with a hydrogen stream containing a polluting species based on a carbonyl-containing compound: possibly CO or CH₂O.

According to one variant of the invention, at least one polluting species is delivered to the anode with a gas containing a sulfur-containing species: possibly H₂S, CS₂, SO₂.

According to one variant of the invention, at least one polluting species is delivered to the cathode with a gas containing SOₓ where x=1 or x=2.

According to one variant of the invention, at least one polluting species is delivered to the cathode with a gas containing NO_{y} where y=1 or y=2.

According to one variant of the invention, at least one polluting species is delivered in the stream feeding the anode and in the stream feeding the cathode.

According to one variant of the invention, at least one polluting species is delivered to the anode or to the cathode by injecting species that are able to decrease the proton conductivity of said ion exchange membrane.

According to one variant of the invention, the polluting species is NH₃.

Another subject of the invention is a device for measuring the reproducibility of N unitary ion exchange membrane/electrode assemblies, comprising:

a stack of N elementary cells fed with a first stream at the anode and with a second stream at the cathode;

means for measuring at least one electrochemical parameter of each assembly;

means for comparing said electrochemical parameter measurements;

a first means of supplying a first stream to the anode; and

a second means for supplying a second stream to the cathode, characterized in that it comprises at least:

a third means for supplying at least one polluting agent communicating with at least the first or the second supply means.

According to one variant of the invention, the third means comprises a container of polluting agent connected to the first or to the second supply means.

According to one variant of the invention, the third means furthermore comprises a means for controlling the flow rate of the polluting agent delivered.

According to one variant of the invention, the first means comprises a container of hydrogen.

According to one variant of the invention, the second means comprises an air intake.

### BRIEF DESCRIPTION OF THE DRAWINGS

The invention will be better understood and other advantages will become apparent on reading the following nonlimiting description, and by virtue of the appended figures, in which:

FIGS. 1a and 1b illustrate a schematic showing the operating principle behind a PEMFC fuel cell;

FIG. 2 illustrates the variation in cell voltage for three MEAs of a first batch, called batch No. 1, when 250 ppb H₂S is present in the fuel first stream;

FIGS. 3a and 3b respectively illustrate electrochemical impedance spectra for the three MEAs of said first batch in their initial state and after 50 hours of poisoning with 250 ppb H₂S contained in the fuel first stream, these measurements being obtained at 0.6 A cm⁻²;

FIG. 4 illustrates the variation in cell voltage for three MEAs of a second batch, called batch No. 2, when 250 ppb H₂S is present in the fuel first stream;

FIGS. 5a and 5b respectively illustrate electrochemical impedance spectra for the three MEAs of said second batch in their initial state and after 50 hours of poisoning with 250 ppb H₂S contained in the fuel first stream, these measurements being obtained at 0.6 A cm⁻²;

FIG. 6 illustrates an example of a device according to the invention allowing the present invention to be implemented.

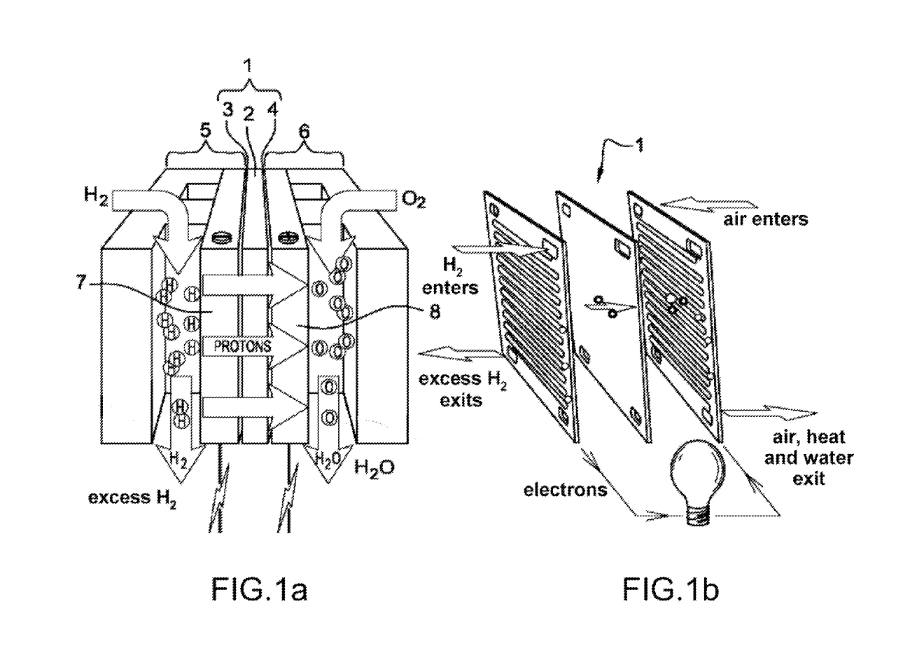

### DETAILED DESCRIPTION

One subject of the present invention is thus a method consisting in characterizing a series of MEAs under operating conditions while using a polluting agent that is present in at least one of the feed streams.

The Applicant thus proposes, for example, to evaluate the performance of an MEA stack when a polluting agent is present in the fuel.

In a stack of perfectly identical MEAs the impact of poisoning by an H₂S polluting agent present in the stream of H₂ fuel is the same. In an MEA assembly with slight structural variations (loading, composition of the ink, etc.), the use of a polluting agent, according to the present invention, amplifies differences in performance.

For example, at the anode only a limited number of active sites are needed to establish a current. With pure hydrogen, the difference in performance between two anodes with similar loading is therefore minimal.

The use of a pollutant such as H₂S, for example, may be particularly relevant. Specifically, in the presence of a given amount of a pollutant such as H₂S, the same number of active sites are poisoned because H₂S is very easily and very strongly adsorbed by platinum. The number of active sites is therefore reduced and the difference between two anodes is amplified.

The pollutant may be a sulfur-containing compound (H₂S, CS₂, SO₂, etc.) or a carbonyl-containing compound (CO, CH₂O, etc.).

The solution proposed in the present invention thus allows the differences between at least two MEAs to be identified, these differences notably arising possibly from a slight difference in catalyst loading, a slight difference in the structure of the active layer, or a slight difference in the compositions of the materials used to manufacture the MEAs.

This solution therefore allows very small differences to be detected, which differences would not be detectable with conventional “quality control methods”. In the context of a pilot MEA manufacturing line, this solution may be used to test the reproducibility of the MEAs by taking samples from a given batch or from various batches.

It may also be advantageous to test variation in reproducibility by injecting a stream at the cathode also containing a polluting species.

In the conventional case where the oxygen feed may notably take the form of an air feed, it may be advantageous to inject a controlled amount of a species such as SO_{X} or NO_{y}.

The polluting species may be injected into one of the streams feeding the electrodes: anode or cathode, but may also be injected in order to act on the membrane, for example NH₃ may be injected into the fuel (H₂) or into the oxidant (air).

Use of this type of pollutant for example allows slight differences in the ion exchange capacity of the proton exchange membranes to be evaluated.

The pollutant may therefore also be ammonia, ammonium ions (NH₄⁺) or any other cations able to exchange through the ionomer membrane (Na⁺, Ca⁺, K⁺, etc.).

The difference in performance may be measured by way of a voltage measurement and by determining the polarization resistance (low-frequency impedance, in the case of hydrogen sulfide) or ohmic resistance (high-frequency impedance, in the case of ammonia).

The uniformity in the performance of the stack of tested MEAs is measured by calculating the relative standard deviation, i.e. the ratio of the standard deviation to the average.

It will be recalled that the standard deviation is defined by the following relationship:

E=[1/nΣ(nᵢ−m)²]^{1/2}

where n is the number of trials and m is the average of the voltage values measured, nᵢ being the value of each of the voltages measured.

A relative standard deviation of near zero means that the performance of the MEAs is repeatable/reproducible. A reproducibility level may be defined from these measurements.

Example of a Test Method According to the Invention Applied to a First Batch (Batch No. 1) of 3 MEAs:

The Applicant tested a first batch (batch No. 1) of MEAs consisting of three MEAs. The three MEAs of this batch were tested under the same conditions with 250 ppb H₂S.

The performance of the MEAs at t₀ corresponds to the performance in pure hydrogen. The relative standard deviation in pure hydrogen is 1%. In pure hydrogen, the performance of these three MEAs is therefore practically the same.

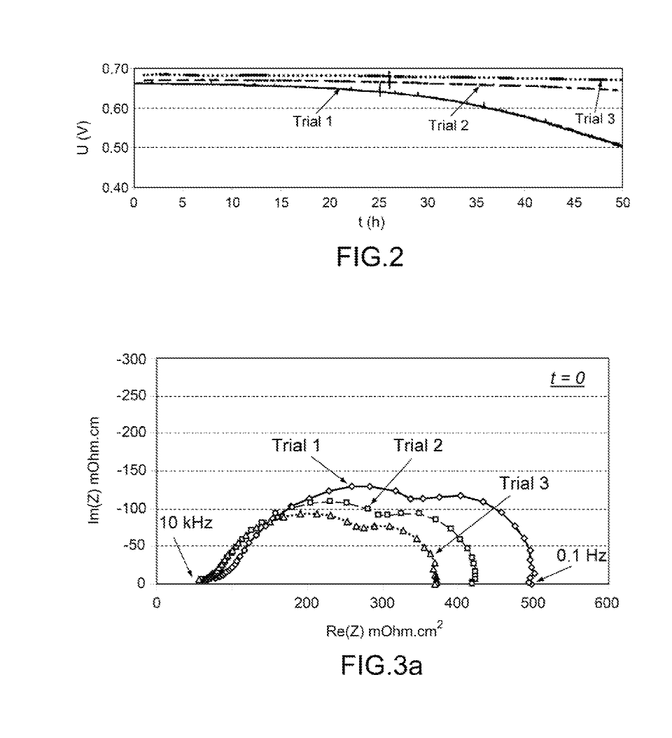

Next, the MEAs were fed with a H₂ fuel stream containing a polluting species, for example H₂S; FIG. 2 illustrates the variation in the performance obtained over time (shown in hours) by measuring the voltage U of the cell in volts.

Poisoning with 250 ppb H₂S over 50 hours led to a voltage drop of 165 mV, 31 mV and 16 mV for Trial 1, Trial 2 and Trial 3, respectively. The relative standard deviation after 50 hours of exposure was therefore 15%. The performance of these three MEAs was therefore no longer the same. The slight differences in performance seen in pure hydrogen were amplified by the H₂S poisoning.

It may also be very advantageous to carry out measurements using a signal generated by exciting oscillations in the applied current, in order to obtain oscillations in the measured voltage and thus allow a complex impedance and a real impedance to be defined.

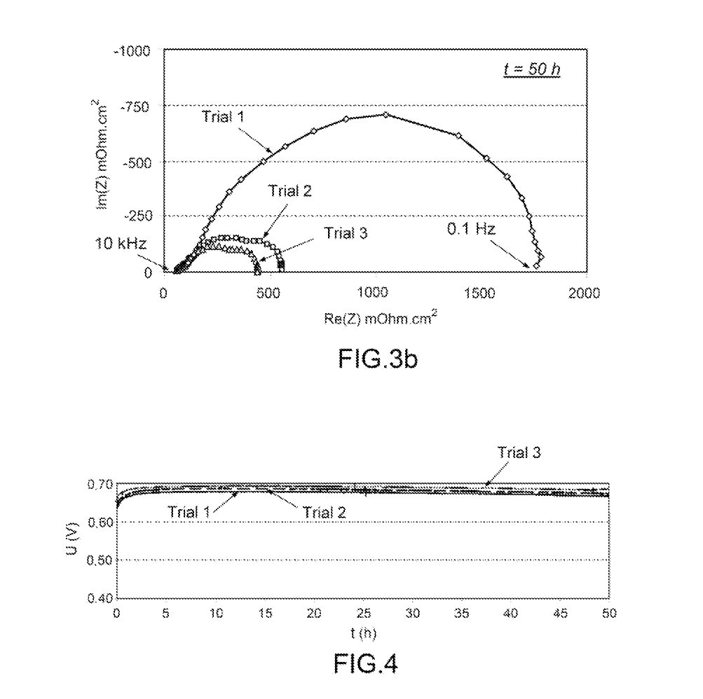

FIGS. 3a and 3b thus show electrochemical impedance spectra for the three MEAs of batch No. 1 in the initial state and after 50 hours of poisoning with 250 ppb, respectively, these measurements being obtained at 0.6 A·cm⁻².

The measurements taken at 10 kHz are representative of the ohmic resistance of the membrane, the measurements taken at 1 Hz being representative of the polarization resistance of the catalyst at the anode.

A difference in performance in pure hydrogen (at t₀) was observed in the electrochemical impedance spectra and notably in the polarization resistance. The resistance differences at low frequencies (typically 0.1 Hz) exhibited very different behaviors at t₀ and after 50 hours, as the curves in FIGS. 3a and 3b show.

The relative standard deviation of the polarization resistance in pure hydrogen was 15% (FIG. 3a).

This difference was then amplified by poisoning: after 50 hours of exposure to H₂S, the relative standard deviation in the polarization resistances was 80% (FIG. 3b).

Example of a Test Method According to the Invention Applied to a Second Batch (Batch No. 2) of 3 MEAs:

Three MEAs of another batch were tested under the same conditions with 250 ppb H₂S. The performance of the MEAs at t₀ corresponds to the performance in pure hydrogen. The relative standard deviation in pure hydrogen is 1%. In pure hydrogen, the performance of these three MEAs is therefore practically the same.

FIG. 4 illustrates the variation in the performance obtained over time by measuring the voltage U of the cell in volts.

Poisoning with 250 ppb H₂S over 50 hours led to a voltage drop of smaller than 5 mV for Trial 1, Trial 2 and Trial 3. The relative standard deviation after 50 hours of exposure was 1%. The performance of these three MEAs remained practically the same.

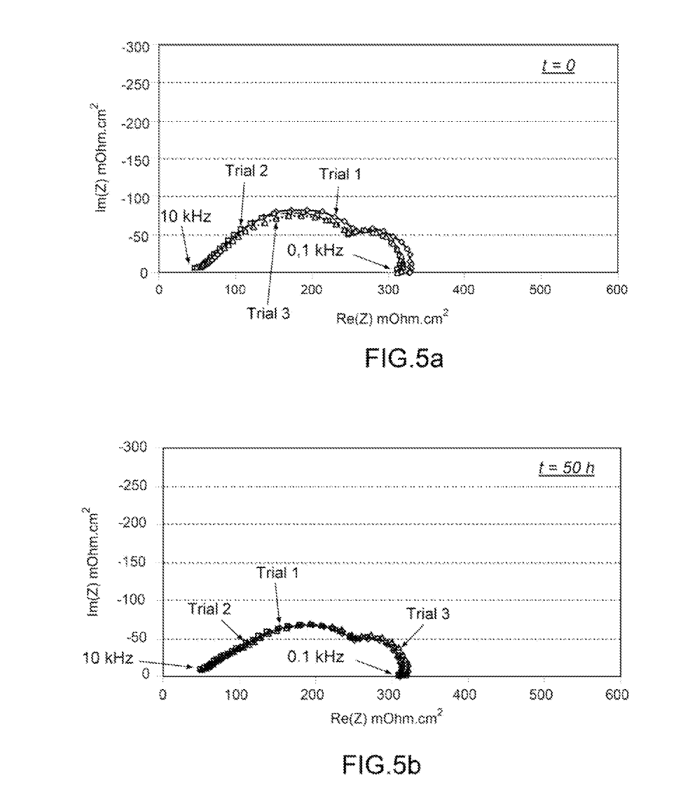

FIGS. 5a and 5b thus show electrochemical impedance spectra for the three MEAs of batch No. 2, in the initial state and after 50 hours of poisoning with 250 ppb, respectively, these measurements being obtained at 0.6 A·cm⁻².

The reproducibility of the performance of the MEAs in pure hydrogen (at t₀) was also observed in the electrochemical impedance spectra (FIG. 5a) and notably in the polarization resistance. The relative standard deviation in the polarization resistance in pure hydrogen was 2%. This difference was then attenuated by the poisoning: after 50 hours with a stream containing H₂S, the relative standard deviation in the polarization resistances was 1% (FIG. 5b).

It would thus appear that for batch No. 1, the relative standard deviation in the voltage passes from 1% in pure hydrogen to 15% after 50 hours of exposure to H₂S. The relative standard deviation in the polarization resistance passes from 15% to 80%, respectively. For batch No. 2, the relative standard deviation in the voltage remains at 1% despite the 50 hours of exposure to H₂S. The relative standard deviation in the polarization resistance is attenuated from 2% to 1%.

It would therefore appear that the solution, according to the present invention, of poisoning with a polluting agent H₂S introduced into the fuel stream of these MEAs indeed allows differences in their performance to be amplified and therefore the reproducibility of various MEAs to be tested with precision.

Example of a Device Allowing the Test Method According to the Invention to be Implemented:

This may essentially be a testbed comprising a certain number of means in common with those described in the patent of Samsung relating to a method and a testbed for testing an MEA stack, US 2008/0197857.

Thus an exemplary testbed according to the invention may comprise the entire line for assembling MEAs, at constant temperature and humidity, into cells fed by a first means supplying fuel and a second means supplying oxidant coupled to a regulating system Reg, and the equipment for measuring the performance parameters of each MEA. The bed also enables activation of the MEAs and the purge process via purging means P_{urge}. In addition according to the invention a third means for supplying a polluting species is provided.

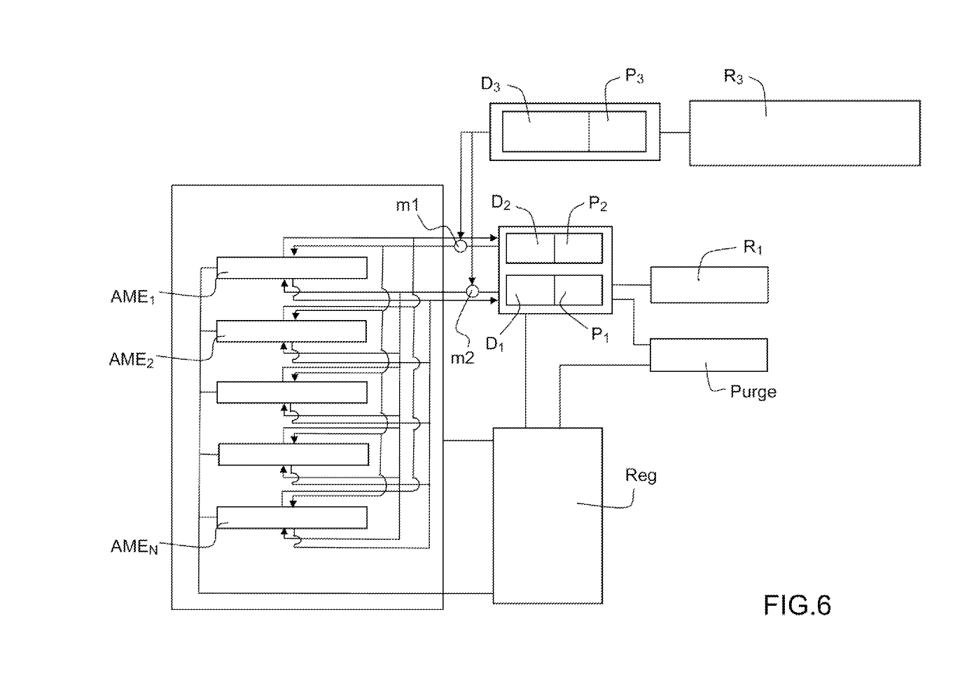

As illustrated in FIG. 6, a stack of MEAs: AME₁, AME₂, . . . , AME_{N} is fed with a first stream containing H₂ and a second stream containing O₂.

The stream of H₂ comes from a reservoir R1 of H₂ coupled to a pump P1 and a flowmeter D1.

Oxygen from the air is pumped via a pump P2 coupled to a flowmeter D2.

The polluting agent is taken from a container R3 of polluting agent, the container possibly for example being a gas bottle, a pump P3 is also provided to ensure supply of the polluting agent, and a flowmeter D3 for the distribution of said polluting agent. The polluting agent may be mixed with the main fuel or oxidant streams at the connections m1 or m2. A regulation system Reg, such as described above, is also provided.

1. A method for measuring the reproducibility of the performance of N unitary ion exchange membrane/electrode assemblies, where N is an integer strictly greater than 1, each assembly containing an ion exchange membrane located between an anode fed with a first stream and a cathode fed with a second stream and possessing cell voltage characteristics, comprising the following steps:
delivering to each unitary assembly a stream containing at least one polluting species for a given time;
measuring at least one electrochemical parameter of each assembly; and
comparing said measurements so as to evaluate the reproducibility of said assemblies.

2. The method for measuring the reproducibility of the performance of N unitary ion exchange membrane/electrode assemblies as claimed in claim 1, in which the electrochemical measurement is a measurement of the voltage between the anode and the cathode.

3. The method for measuring the reproducibility of N unitary ion exchange membrane/electrode assemblies as claimed in claim 1, in which the electrochemical measurement is a measurement of the impedance of said cell.

4. The method for measuring the reproducibility of the performance of N unitary ion exchange membrane/electrode assemblies as claimed in claim 1, further comprising:
determining the standard deviation of all of said measurements; and
comparing said standard deviation with a predefined tolerance threshold value.

5. The method for measuring the reproducibility of the performance of N unitary ion exchange membrane/electrode assemblies as claimed in claim 2, in which the measurement of the voltage of each assembly is carried out by applying a DC current.

6. The method for measuring the reproducibility of the performance of N unitary ion exchange membrane/electrode assemblies as claimed in claim 3, in which the impedance measurement is carried out by applying current oscillations allowing the electrochemical impedance spectra of said assemblies to be defined.

7. The method for measuring the reproducibility of the performance of N ion exchange membrane/electrode assemblies as claimed in claim 1, in which the anode comprises a platinum-containing catalyst.

8. The method for measuring the reproducibility of the performance of N ion exchange membrane/electrode assemblies as claimed in claim 1, in which the anode comprises a catalyst containing platinum and ruthenium.

9. The method for measuring the reproducibility of the performance of N ion exchange membrane/electrode assemblies as claimed in claim 7, in which at least one polluting species is delivered to the anode with a hydrogen stream containing a polluting species based on a carbonyl-containing compound: possibly CO or CH₂O.

10. The method for measuring the reproducibility of the performance of N ion exchange membrane/electrode assemblies as claimed in claim 8, in which at least one polluting species is delivered to the anode with a gas containing a sulfur-containing species: possibly H₂S, CS₂, SO₂.

11. The method for measuring the reproducibility of the performance of N unitary ion exchange membrane/electrode assemblies as claimed in claim 1, in which at least one polluting species is delivered to the cathode with a gas containing SO_{X} where x=1 or x=2.

12. The method for measuring the reproducibility of the performance of N unitary ion exchange membrane/electrode assemblies as claimed in claim 1, in which at least one polluting species is delivered to the cathode with a gas containing NO_{y} where y=1 or y=2.

13. The method for measuring the reproducibility of N unitary ion exchange membrane/electrode assemblies as claimed in claim 1, in which at least one polluting species is delivered in the stream feeding the anode and in the stream feeding the cathode.

14. The method for measuring the reproducibility of the performance of N unitary ion exchange membrane/electrode assemblies as claimed in claim 1, in which at least one polluting species is delivered to the anode or to the cathode by injecting species that are able to decrease the proton conductivity of said ion exchange membrane.

15. The method for measuring the reproducibility of the performance of N unitary ion exchange membrane/electrode assemblies as claimed in claim 14, In which the polluting species is NH₃.

16. A device for measuring the reproducibility of the performance of N unitary ion exchange membrane/electrode assemblies, comprising:
a stack of N elementary cells fed with a first stream at the anode and with a second stream at the cathode;
means for measuring at least one electrochemical parameter of each assembly;
means for comparing said electrochemical parameter measurements;
a first means of supplying a first stream to the anode; and
a second means for supplying a second stream to the cathode, characterized in that it comprises at least:
a third means for supplying at least one polluting agent communicating with at least the first or the second supply means.

17. The device for measuring the reproducibility of the performance of N unitary ion exchange membrane/electrode assemblies as claimed in claim 16, in which the third means comprises a container of polluting agent connected to the first or to the second supply means.

18. The device for measuring the reproducibility of the performance of N unitary ion exchange membrane/electrode assemblies as claimed in claim 16, in which the third means furthermore comprises a means for controlling the flow rate of the polluting agent delivered.

19. The device for measuring the reproducibility of the performance of N unitary ion exchange membrane/electrode assemblies as claimed in claim 16, in which the first means comprises a container of hydrogen.

20. The device for measuring the reproducibility of the performance of N unitary ion exchange membrane/electrode assemblies as claimed in claim 16, in which the second means comprises an air intake.
